(19) United States
(12) Patent Application Publication
(10) Pub. No.: US 2007/0181965 A1
(43) Pub. Date: Aug. 9, 2007

(54) Chip element, manufacturing method thereof, and electronic device or equipment using same

(75) Inventors: Tadahiro Ohmi, Miyagi (JP); Akihiro Morimoto, Miyagi (JP)

Correspondence Address: FOLEY AND LARDNER LLP;SUITE 500, 3000 K STREET NW, WASHINGTON, DC, 20007, US

(73) Assignee: TOHOKU UNIVERSITY

(21) Appl. No.: 11/702,195

(22) Filed: Feb. 5, 2007

(30) Foreign Application Priority Data
Feb. 6, 2006 (JP) 2006-028607

(51) Int. Cl. H01L 29/00

(52) U.S. Cl. 257/499

(57) ABSTRACT

In a chip element having a substrate, an impedance element formed on the substrate, and a plurality of electrodes formed on the substrate to be connected to the impedance element, the substrate is formed of a low-permittivity material having a permittivity low enough to decrease the parasitic capacitance in a GHz range. The substrate further includes at least a synthetic resin and an inorganic compound.

This application claims priority to prior Japanese patent application JP 2006-28607, the disclosure of which is incorporated herein by reference.

### BACKGROUND OF THE INVENTION

The present invention relates to a leadless chip element, and particularly to a chip resistor element and a chip inductance element to be mounted on a printed circuit board or the like. The present invention also relates to a manufacturing method of such element and electronic devices or electronic equipment using such element.

Chip elements, such as chip resistances, chip inductors, and chip capacitors, are widely used as components mounted on a printed circuit board. These chip elements are capable of improving the packaging density per unit area.

These chip elements are produced by forming a wiring pattern for providing a necessary function, on a substrate of a ceramic such as alumina or ferrite, or embedded in the ceramic substrate, covering the wiring pattern with glass or a resin, and forming electrodes at ends of the wiring pattern.

The reason why a ceramic is used as a packaging material for the wiring pattern is that a ceramic gives thermal strength to the chip element which is subjected to a high temperature process, such as a solder reflowing process, at 200° C. to 300° C. when mounted on a printed circuit board of glass epoxy or the like.

The chip elements, mounted on printed circuit boards, are also used as terminating resistances for microstrip lines which are widely used as signal transmission lines, or high-frequency signal matching elements for cellular mobile phones, for example. The signal transmission lines typically have a characteristic impedance of 50Ω.

On the other hand, it is also a typical practice that, in order to provide a 50Ω wiring with sufficient signals from an active element, such as an LSI, a buffer circuit is formed at the input and output portions of the LSI and the 50Ω wiring is driven by a large current generated by the buffer circuit.

It is expected that these chip elements are used in a higher frequency range, namely, in a frequency band of 1 GHz or higher (or, a GHz range).

Japanese Unexamined Patent Applicaion Publication (JP-A) No. 2005-026616 (which will be, hereafter, referred to as Patent Publication 1) describes a type of such chip elements. In the chip element disclosed in Patent Publication 1, a low-permittivity resin is used for a substrate forming the chip element.

However, according to the technique disclosed in Patent Publication 1, although the chip element has decent thermal strength, the substrate itself will thermally expand or contract due to change in service environment temperature, resulting in problems that the resistance value varies in accordance with the service temperature, or disconnection occurs in the circuit.

### SUMMARY OF THE INVENTION

It is therefore an object of the present invention to provide a chip element using a high-quality and low-permittivity resin, which has a low coefficient of thermal expansion and low variation in resistance value under change of service environment temperature, and causes no problem, such as disconnection.

It is another object of the present invention to provide a method of manufacturing a chip element using a high-quality and low-permittivity resin, which has a low coefficient of thermal expansion and low variation in resistance value under change of service environment temperature, and causes no problem, such as disconnection.

It is still another object of the present invention is to provide electronic equipment having a chip element using a high-quality and low-permittivity resin, which has a low coefficient of thermal expansion and low variation in resistance value under change of service environment temperature, and causes no problem, such as disconnection.

According to one aspect of the present invention, there is provided a chip element which includes a substrate, an impedance element formed on the substrate, and a plurality of electrodes formed on the substrate to be connected to the impedance element. In the chip element, the substrate is formed of a low-permittivity material having a permittivity low enough to decrease the parasitic capacitance in a GHz range. The substrate further includes at least a synthetic resin and an inorganic compound.

According to another aspect of the present invention, there is provided a method of manufacturing a chip element which includes the steps of preparing a substrate, forming an impedance element on the substrate, and forming a plurality of electrodes on the substrate to be connected to the impedance element. In the method, a low-permittivity material having a permittivity low enough to decrease the parasitic capacitance in a GHz range is used as the substrate. The substrate further includes at least a synthetic resin and an inorganic compound.

According to the present invention, as described above, it is possible to provide a chip element using a high-quality and low-permittivity resin, which has a low coefficient of thermal expansion, low variation in resistance value under change of service environment temperature, and causes no problem, such as disconnection, a manufacturing method of such chip element, and electronic equipment having such chip element.

### BRIEF DESCRIPTION OF THE DRAWING

FIG. 1 is a diagram showing an example of a chip resistor element according to the present invention;

FIG. 2 is a diagram illustrating an example of a laminated low-permittivity substrate according to the present invention;

FIG. 3 is an exploded perspective view showing an example of a chip inductor element according to the present invention; and

FIG. 4 is a diagram plotting the coefficients of thermal expansion versus the thermal shock test results of Table 1.

### DESCRIPTION OF THE PREFERRED EMBODIMENT

The present invention will be described in more detail.

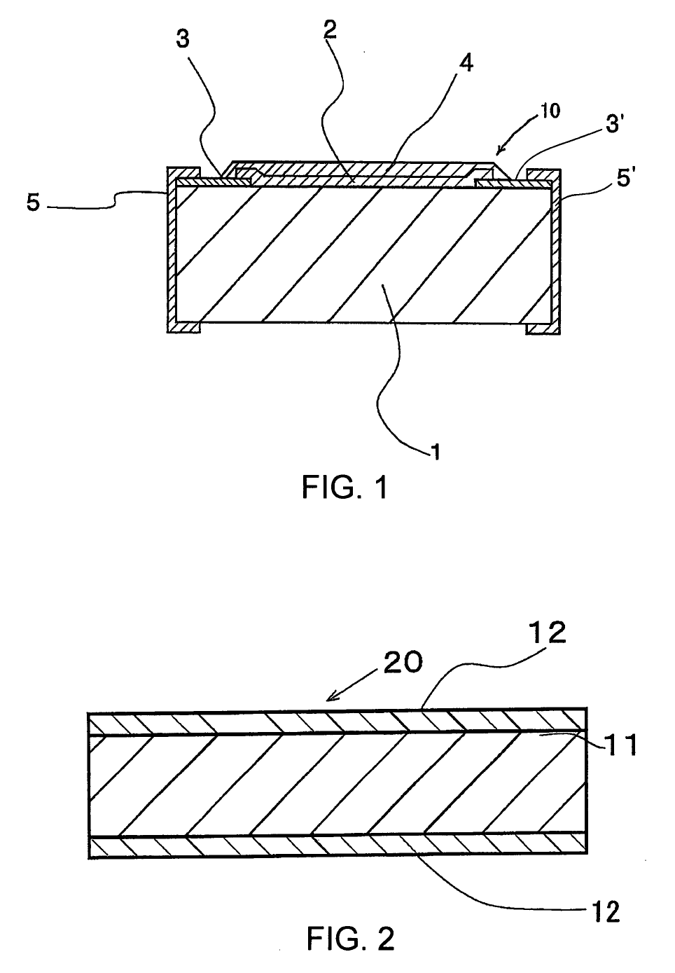

Referring to FIG. 1, a chip element 10 according to an example of the present invention consists of a chip resistor element and has a low-permittivity substrate 1, a resistor 2 formed on the low-permittivity substrate 1, first electrodes 3 and 3′ for establishing electrical contacts with the ends of the resistor 2, a protective film 4 for protecting the surface of the resistor 2, and second electrodes 5 and 5′ for establishing electrical contacts with the first electrodes 3 and 3′, respectively.

Referring to FIG. 2, a laminated low-permittivity substrate 20 according to an example of the present invention is formed by laminating a poly-olefin resin 12 on the opposite surfaces of a porous silica plate 11 by a laminating method.

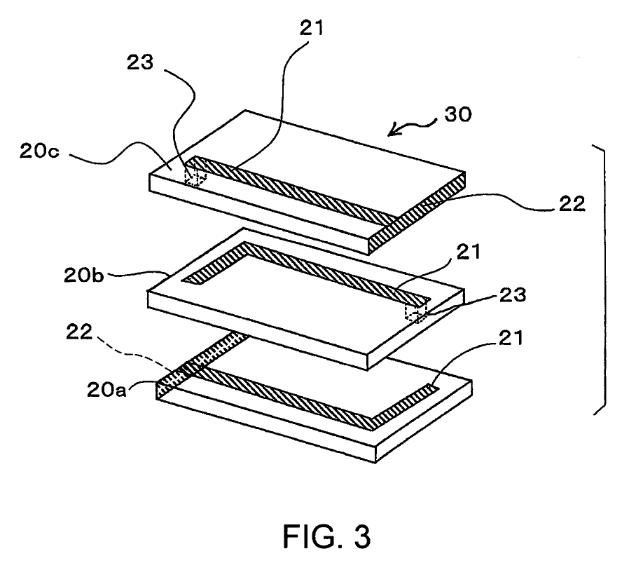

Referring to FIG. 3, a chip element 30 according to an example of the present invention consists of a laminated-type chip inductor element, and is comprised of a stack of three substrates 20a, 20b, and 20c which are respectively formed by using the laminated low-permittivity insulator substrate 20 according to the example shown in FIG. 2. The first substrate 20a has a wiring 21 formed by conductive paste printed thereon. Each of the second and the third substrates 20b and 20c has a similar wiring 21 and a via hole (connection hole) 23 for interconnecting the wiring 21 on that substate and an underlayer wiring 21 on the lower substrate. The third substrate 20c is further provided with a side electrode 22 at least on a side face thereof. The first substrate 20a also has a similar side electrode 22 connected to the wiring 21.

As described above, the chip element of the present invention includes at least one of a chip resistor element and a chip inductor element.

The chip element of the present invention includes an impedance element and a plurality of electrodes connected to the impedance element, both formed on the low-permittivity substrate 1, 20. In this chip element, the substrate 1, 20 is formed of a low-permittivity material having a permittivity that is low enough to decrease the parasitic capacitance in a GHz range. The substrate 1, 20 further includes at least a synthetic resin and an inorganic compound.

According to the present invention, the synthetic resin preferably includes at least one selected from the group consisting of fluororesin, acrylic resin, epoxy resin, liquid crystal resin, phenolic resin, polyester resin, modified polyphenyl ether resin, bis-maleimide triazine resin, modified polyphenylene oxide resin, silicon resin, benzocylobutene resin, polyethylene naphthalate resin, polycyclo-olefln resin, poly-olefin resin, cyanate ester resin, and melamine resin.

Among these synthetic resins, a resin having a low coefficient of thermal expansion is particularly preferable. The substrate formed of this synthetic resin in composite with an inorganic compound should preferably has a coefficient of thermal expansion of 100 ppm/° C. or lower at a temperature from room temperature to 100° C., more preferably 50 ppm/° C. or lower, and most preferably 30 ppm/° C. or lower.

Examples of such preferable resins include fluororesin, epoxy resin, liquid crystal resin, poly-olefin resin, silicon resin, and polyethylene naphthalate resin.

The inorganic compound contained in the substrate can be mixed with the synthetic resin, or laminated as an inorganic compound layer on the synthetic resin layer. The inorganic compound to be mixed with the synthetic resin includes at least one of an inorganic filler in the form of particles, inorganic fibers and an inorganic structure, in such an amount that the relative permittivity of the substrate is not notably increased, in order to decrease the coefficient of thermal expansion. Similarly, the inorganic compound to be laminated on the synthetic resin layer should not notably increase the relative permittivity of the substrate. In either case, the relative permittivity of the substrate is preferably 4 or lower, and more preferably 3 or lower.

As an example of the substrate according to the present invention, the synthetic resin contains a particulate inorganic filler such as glass beads, an inorganic fibrous compound selected from ceramic fibers such as alumina fibers, glass wool, rock wool, carbon fibers, potassium titanate fibers and zeolite fibers, or an inorganic structure formed of an inorganic compound into a predetermined structure such as a frame. When the inorganic fibrous compound or the inorganic structure is used in the substrate, a layer of the synthetic resin may be formed on the top and rear surfaces of a molding having a sheet or film shape by a well-known laminating method or impregnation method so that the surfaces are made resinous. In this case, advantages are obtained that the smoothness can be easily ensured for the top and rear surfaces, and the accuracy of resistance pattern formation can be improved.

Another example of the substrate according to the present invention is one in which the synthetic resin layer is formed at least one of the top and rear surfaces of a base member consisting of an inorganic compound and having a sheet or film shape. The inorganic compound may be a fabric of inorganic fibers or an inorganic structure having a frame structure, similarly to the above-mentioned example, so long as the inorganic compound has a sheet shape.

As still another example of the substrate according to the present invention, the inorganic compound layer may be formed at least one of the top and rear surfaces of a base member of the synthetic resin having a sheet or film shape by a well-known sol-gel method or adhesion method. In this case, advantages are obtained that the heat resistance of the surface on which the inorganic compound layer is formed is improved, for example. Alternatively, a layer or layers of the synthetic resin and a layer or layers of the inorganic compound may be used in composite by laminating these layers to each other.

Examples of the impedance elements using the substrate according to the present invention include a chip resistor element and a chip inductance element, in which the effect of decreasing the substrate permittivity can be fully attained.

Specific examples of the present invention will be described below.

### EXAMPLE 1

A chip resistor element according to Example 1 of the present invention has similar configuration to that of FIG. 1. Referring to FIG. 1, the chip element 10 includes a low-permittivity substrate 1, a resistor 2 formed on the low-permittivity substrate 1, first electrodes 3 and 3′ for establishing electrical contacts with the resistor 2, a protective film 4 for protecting the resistor surface, and second electrodes 5 and 5′ for establishing electrical contacts with the first electrodes 3 and 3′.

The low-permittivity substrate 1 was formed by distributing glass beads having a particle size of 100 nm to 10 μm in poly-olefin resin having a permittivity of 2 to 3 and a thermal decomposition starting temperature of 200 to 300° C. The effect of the present invention can be sufficiently obtained by mixing 1 to 1000 parts by weight of the glass beads to 100 parts by weight of the poly-olefin resin.

If the quantity of the added glass beads is smaller than the above value, it will be difficult to decrease the coefficient of thermal expansion. In contrast, if the quantity is larger than the above value, it will cause problems, such as brittleness of the substrate 1. If the particle size of the glass beads is smaller than 100 nm, it will be difficult to distribute them and the process will become complicated. If the particle size is greater than 10 μm, in contrast, the surface of the substrate 1 will become uneven due to the glass beads, which makes it difficult to form the resistor 2 thereon. In Example 1 of the present invention, 200 parts by weight of the glass beads (with a particle size of 2 to 3 μm) was mixed to 100 parts by weight of poly-olefin resin. When measured, it was found that the coefficient of thermal expansion of 70 ppm/° C. before the mixture of the glass beads was decreased to 50 ppm/° C. The relative permittivity of the substrate was measured by a resonance cavity perturbation method and a value of 2.9 was obtained.

A resistor was formed on the substrate 1 by a well-known screen printing method, and sintered at 200° C. to obtain the resistor 2. The resistor may be formed by other known methods, such as a mask vapor deposition method, a spreading or painting method, and a sputtering method. An electrode 3, 3′ was then formed by a mask vapor deposition method, and an SOG protective film 4 was formed by a spreading or painting method (a method of applying a SOG layer over the resin 2 and drying and sintering it) to a thickness of 5 μm, whereby a chip resistor element was obtained.

For comparison, a chip resistor element fabricated in the same manner was formed on a substrate having no glass beads incorporated, and thermal shock tests were conducted at temperatures of 125° C. and −40° C. The chip resistor element formed on the substrate 1 having glass beads incorporated therein showed no change in characteristics even after 1000 cycles of the test but the resistance value was increased by 10% after 3000 cycles of the test. In contrast, the chip resistor element formed on the substrate having no glass beads incorporated therein showed 10% increase in the resistance value after 500 cycles of the test.

Next, various test specimens were prepared while changing the quantities of a synthetic resin serving as a base, and glass beads or liquid crystal polymer serving as a filler, and similar tests were conducted on the test specimens. Results obtained are shown in Table 1 below.

TABLE 1

| | relative | | | | relative | | |
|---|---|---|---|---|---|---|---|
| | permittivity | | relative | supply | permittivity | coefficient | |
| | of | | permittivity | amount | of composite | of thermal | |
| base resin | base resin | filler | of filler | of filler | substrate | expansion | thermal shock test results |
| poly-olefin | 2.2 | glass beads | 3.9 | 200 | 2.9 | 50 ppm/° C. | resistance increased by 10% |
| | | | | weight | | | after 3000 cycles |
| | | | | parts | | | |
| poly-olefin | 2.2 | — | 13 | — | 2.2 | 70 ppm/° C. | resistance increased by 10% |
| | | | | | | | after 500 cycles |
| poly-olefin | 2.2 | liquid crystal | 2.9 | 100 | 2.5 | 55 ppm/° C. | resistance increased by 10% |
| | | polymer | | weight | | | after 3000 cycles |
| | | (particulate) | | parts | | | |
| poly-olefin | 2.2 | liquid crystal | 2.9 | 200 | 2.7 | 30 ppm/° C. | resistance increased by 10% |
| | | polymer | | weight | | | after 5000 cycles |
| | | (fibrous) | | parts | | | |
| liquid | 2.9 | glass beads | 3.9 | 100 | 3.2 | 5 ppm/° C. | resistance increased by 10% |
| crystal resin | | | | weight | | | after 5000 cycles |
| | | | | parts | | | |
| epoxy resin | 3.4 | — | — | — | 3.4 | 120 ppm/° C. | resistance increased by 10% |
| | | | | | | | after 100 cycles |
| epoxy resin | 3.4 | glass beads | 3.9 | 200 | 3.7 | 90 ppm/° C. | resistance increased by 10% |
| | | | | weight | | | after 300 cycles |
| | | | | parts | | | |
| poly-olefin | 2.2 | alumina | 10 | 200 | 3.9 | 30 ppm/° C. | resistance increased by 10% |
| | | (fibrous) | | weight | | | after 500 cycles |
| | | | | parts | | | |

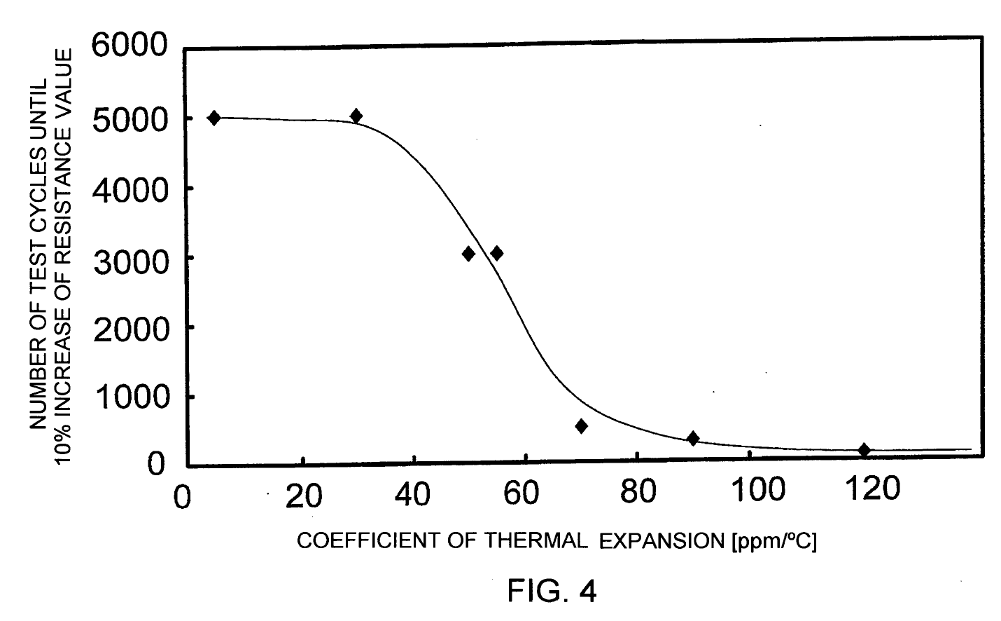

The results of Table 1 were plotted in the relationship between the coefficient of thermal expansion and the number of thermal shock test cycles conducted until the resistance value was increased by 10%, and the graph of FIG. 4 was obtained. It is seen from Table 1 and FIG. 4 that, when used alone, thermally expandable epoxy resin started improving its characteristics when the coefficient of thermal expansion becomes lower than 100 ppm/° C., and that the coefficient of thermal expansion is preferably 50 ppm/° C. or lower, and more preferably 30 ppm/° C. or lower.

The chip resistor element of the present invention, which employs the low-permittivity substrate 1 having a low thermal expansion coefficient as a substrate, is able to reduce the parasitic capacitance more in comparison with the conventional techniques, and thus enables formation of a chip resistance the resistance value of which is not deteriorated even in a high frequency range.

The chip resistor element according to Example 1, having a low parasitic capacitance component and exhibiting no deterioration in the resistance value even in a high frequency range, is able to form a high frequency circuit having little characteristic degradation. Additionally, since a mixture of a resin and an inorganic compound having high heat resistance and a low coefficient of thermal expansion is used as a substrate material, deterioration of thermal strength can be prevented during a high temperature process, such as a solder reflowing process. Further, since the coefficient of thermal expansion is decreased, occurrence of a failure, such as disconnection can be suppressed.

### EXAMPLE 2

A laminated low-permittivity substrate 20 according to Example 2 of the present invention has same configuration as that of FIG. 2. Referring to FIG. 2, the laminated low-permittivity substrate 20 was formed by laminating a 50 μm thick layer of poly-olefin resin 12 by a laminating method on the opposite surfaces of a porous silica plate 11 having a thickness of 100 μm and a porosity of 40%. When measured, the relative permittivity and coefficient of thermal expansion of the substrate 20 were 2.4 and 15 ppm/° C., respectively. A resistor 2 was formed on this base in a same manner as in Example 1. When subjected to a thermal shock test, the resistor 2 exhibited no increase in resistance even after 3000 cycles of the test.

### EXAMPLE 3

A porous alumina plate having a porosity of 50% was used in place of the porous silica plate in Example 2. The relative permittivity and the coefficient of thermal expansion of the substrate were 2.8 and 15 ppm/° C., respectively. A resistor 2 was formed on this base in a same manner as in Example 1, and subjected to a thermal shock test. The resistance value was increased by 10% after 5000 cycles of the test.

### EXAMPLE 4

In Example 4, a layer mainly composed of an inorganic compound, such as ceramic, was further formed by a well-known sol-gel method on the surface of the laminated low-permittivity substrate 20 fabricated in Example 2.

The material for this ceramic layer is not particularly specified. In Example 4 of the present invention, a layer mainly composed of alumina was formed into a thickness of 100 nm on the laminated low-permittivity substrate 20 having a thickness of 0.2 mm. This improves the surface heat resistance of the laminated low-permittivity substrate 20, and makes it possible to form a protective glass film having high quality in a stable manner by using a plasma CVD method.

According to Example 4, a 1 μm thick protective film could be obtained, having equivalent performance to that of the protective film 4 (FIG. 1) obtained by the spreading or painting method used in Examples 1 and 2. When the protective film was formed by a plasma CVD method without covering the surface with the layer mainly composed of alumina as described above, a resin decomposition product generated by plasma impact during an initial stage of the CVD process was introduced into the protective film, causing a problem that a desired resistance value could not be obtained, or the protective film could not exhibit sufficient performance due to intrusion of water or the like.

A chip inductor element according to Example 4 of the present invention has similar configuration to that shown in FIG. 3. Referring to FIG. 3, a chip inductor element 30 is formed by stacking substrates 20a, 20b, 20c each having the structure of the laminated low-permittivity insulator substrate 20 of Example 2, and each having a wiring 21 formed by conductive paste printing or the like. Via holes (connection hole) 23 for interconnection with an underlayer wiring, and an electrode 22 on the side face of the stacked body are formed.

The low-permittivity insulator substrate 20 desirably has a low permittivity from the viewpoint of decreasing the inter-wiring parasitic capacitance. While the effect of Example 3 can be obtained if the relative permittivity is lower than that of conventional ceramic materials (having a relative permittivity or about 10 or higher), the relative permittivity is preferably 4 or lower, more preferably 3 or lower, and still more preferably 2.5 or lower. The low-permittivity insulator substrate 20 having a lower permittivity than conventional ceramic materials is able to decrease the parasitic capacitance, and is able to improve the self-resonant frequency of the inductor. Further, since the thermal strength of the substrate is enhanced, the dimensional stability is improved, and the variation in the inductance value caused by change of service temperature can be suppressed. Thus, the substrate 20 is able to provide thermal characteristics equivalent to those of conventional ceramic substrates.

An inductor was formed on an alumina ceramic substrate as a comparative example, which was compared with a case in which an inductor was formed on the laminated low-permittivity substrate 20 used in Example 2, in terms of characteristics. The normalized inductance value at low frequency was 10 nH. In the comparative example using the alumina ceramic substrate, the parasitic capacitance was 50 fF and the self-resonant frequency was 7.1 GHz. In the case of using the laminated low-permittivity substrate 20, the parasitic capacitance was 12.5 fF and the self-resonant frequency was 14.3 GHz. It was found that the usage of the low-permittivity substrate improved the self-resonant frequency, and also improved the usable frequency as an inductance element.

As described above, the chip element according to the examples of the present invention can be used an element in a GHz range, and thus is applicable to various types of electric devices and equipment operating in a GHz range, such as mobile phones and computers.

What is claimed is:

1. A chip element comprising:
a substrate;
an impedance element formed on the substrate; and
a plurality of electrodes formed on the substrate to be connected to the impedance element;
wherein the substrate is formed of a low-permittivity material having a permittivity low enough to decrease the parasitic capacitance in a GHz range, and the substrate further includes at least a synthetic resin and an inorganic compound.

2. The chip element according to claim 1, wherein the synthetic resin includes at least one selected from the group consisting of fluororesin, acrylic resin, epoxy resin, liquid crystal resin, phenolic resin, polyester resin, modified polyphenyl ether resin, bis-maleimide triazine resin, modified polyphenylene oxide resin, silicon resin, benzocylobutene resin, polyethylene naphthalate resin, polycyclo-olefin resin, poly-olefin resin, cyanate ester resin, and melamine resin.

3. The chip element according to claim 1, wherein the low-permittivity material has a relative permittivity of 4 or lower.

4. The chip element according to claim 1, wherein the substrate is composed of a mixture in which the synthetic resin is mixed with the inorganic compound taking a form selected from a particulate inorganic filler, an inorganic fibrous compound, and an inorganic structure.

5. The chip element according to claim 1, wherein the substrate has a sheet- or film-shaped base member of the inorganic compound and a layer of the synthetic resin formed at least one of the top and rear surfaces of the sheet- or film-shaped base member of the inorganic compound.

6. The chip element according to claim 1, wherein the substrate has a sheet- or film-shaped base member of the synthetic resin and a layer of the inorganic compound formed at least one of the top and rear surfaces of the sheet- or film-shaped base member of the synthetic resin.

7. The chip element according to claim 1, wherein the impedance element comprises at least one of a chip resistor element and a chip inductance element.

8. Electronic device having a chip element comprising a substrate, an impedance element formed on the substrate, and a plurality of electrodes formed on the substrate to be connected to the impedance element,
wherein the substrate of the chip element is formed of a low-permittivity material having a permittivity low enough to decrease the parasitic capacitance in a GHz range, and the substrate further includes at least a synthetic resin and an inorganic compound.

9. The electronic device according to claim 8, wherein the synthetic resin includes at least one selected from the group consisting of fluororesin, acrylic resin, epoxy resin, liquid crystal resin, phenolic resin, polyester resin, modified polyphenyl ether resin, bis-maleimide triazine resin, modified polyphenylene oxide resin, silicon resin, benzocylobutene resin, polyethylene naphthalate resin, polycyclo-olefin resin, poly-olefin resin, cyanate ester resin, and melamine resin.

10. The electronic device according to claim 8, wherein the low-permittivity material has a relative permittivity of 4 or lower.

11. The electronic device according to claim 8, wherein the substrate is composed of a mixture in which the synthetic resin is mixed with the inorganic compound taking a form selected from a particulate inorganic filler, an inorganic fibrous compound, and an inorganic structure.

12. The electronic device according to claim 8, wherein the substrate has a sheet- or film-shaped base member of the inorganic compound and a layer of the synthetic resin formed at least one of the top and rear surfaces of the sheet- or film-shaped base member of the inorganic compound.

13. The electronic device according to claim 8, wherein the substrate has a sheet- or film-shaped base member of the synthetic resin and a layer of the inorganic compound formed at least one of the top and rear surfaces of the sheet- or film-shaped base member of the synthetic resin.

14. The electronic device according to claim 8, wherein the impedance element comprises at least one of a chip resistor element and a chip inductance element.

15. A method of manufacturing a chip element comprising the steps of:
preparing a substrate;
forming an impedance element on the substrate; and
forming a plurality of electrodes on the substrate to be connected to the impedance element;
wherein a low-permittivity material having a permittivity low enough to decrease the parasitic capacitance in a GHz range is used as the substrate, the substrate further including at least a synthetic resin and an inorganic compound.

16. The method of manufacturing the chip element according to claim 15, wherein at least one synthetic resin selected from the group consisting of fluororesin, acrylic resin, epoxy resin, liquid crystal resin, phenolic resin, polyester resin, modified polyphenyl ether resin, bis-maleimide triazine resin, modified polyphenylene oxide resin, silicon resin, benzocylobutene resin, polyethylene naphthalate resin, polycyclo-olefin resin, poly-olefin resin, cyanate ester resin, and melamine resin is used as the synthetic resin.

17. The method of manufacturing the chip element according to claim 15, wherein a material having a relative permittivity of 4 or lower is used as the low-permittivity material.

18. The method of manufacturing the chip element according to claim 15, wherein a mixture having the synthetic resin mixed with the inorganic compound taking a form selected from a particulate inorganic filler, an inorganic fibers, and an inorganic structure is used for the substrate.

19. The method of manufacturing the chip element according to claim 15, wherein the substrate is fabricated by forming, on at least one of the top and rear surfaces of a sheet- or film-shaped base member of one of the inorganic compound and the synthetic resin, a layer of the other of the inorganic compound and the synthetic resin.

20. The method of manufacturing the chip element according to claim 15, wherein the impedance element comprises at least one of a chip resistor element and a chip inductance element.
